(19) United States
(12) Patent Application Publication
(10) Pub. No.: US 2002/0101712 A1
(43) Pub. Date: Aug. 1, 2002

(54) Diskette type electronic device

(76) Inventors: Koichi Seno, Yamagata (JP); Yoshimi Hanaika, Yamagata (JP); Makoto Sato, Yamagata (JP)

Correspondence Address: WHITHAM, CURTIS & CHRISTOFFERSON, P.C., 11491 SUNSET HILLS ROAD, SUITE 340, RESTON, VA, 20190, US

(21) Appl. No.: 10/052,333

(22) Filed: Jan. 23, 2002

(30) Foreign Application Priority Data
Jan. 29, 2001 (JP) P.2001-019333

(51) Int. Cl. G06F 1/16; G11C 5/00

(52) U.S. Cl. 361/685; 365/226

(57) ABSTRACT

A diskette type electronic device is attached to a reader/writer for recording and reproducing information on and from an information recording medium provided therein. In the electronic device, a diskette case having a shape substantially identical with a diskette provided with a magnetic disk as the information recording medium. An IC memory is provided as the information recording medium. A communicator communicates information to be recorded on or reproduced from the IC memory with the reader/writer. A detachable power supply unit includes a rechargeable secondary battery which supplies power to the IC memory and the communicator.

### BACKGROUND OF THE INVENTION

The present invention relates to a diskette type electronic device having an outline substantially identical with that of a diskette having a magnetic disk to serve as an information recording medium, and comprising a built-in or removable IC memory to serve as an information recording medium, and a communicator which communicates information to be recorded on or reproduced from the IC memory with a reader/writer when the electronic device is attached thereto.

In a technical field, such as a digital camera, so-called IC memory; e.g., a solid-state floppy disk card (SSFDC), has hitherto been employed as an information recording medium for recording information of large volume, such as stationary or moving images. The IC memory has a built-in semiconductor storage device, and various types of information items can be recorded on and reproduced from the semiconductor storage element.

In association with proliferation of electronic commerce and electronic banking, IC memory is considered a promising information recording medium for recording personal information.

As an external recording device for use with an information processing system; e.g., a computer system, there has already become widespread a reader/writer which enables removal and insertion of a diskette having a magnetic disk as an information recording medium and which records and reproduces various types of information items on and from the magnetic disk.

In order to effect recording and reproduction of information on IC memory through use of such a reader/writer, a so-called diskette type electronic device has already been proposed.

The diskette type electronic device has built-in or removable IC memory and has an outline substantially identical with that of a diskette. Further, the diskette type electronic device is constructed so as to be detachably attached to a reader/writer for recording on and reproducing information from the diskette. The electronic device is further equipped with a communicator for communicating information to be recorded on and reproduced from the IC memory with the reader/writer. In this configuration, the electronic device can record and reproduce information on and from the IC memory by way of the communicator.

In order to supply electronic power to be used for activating the IC memory and the communicator, the related diskette type electronic device has employed a so-called button primary battery, such as “CR2016” or “CR2025” specified by, e.g., JIS (Japanese Industrial Standards).

However, the button primary battery does not have sufficient storage capacity for driving the diskette type electronic device for a long time period. For this reason, power supply is interrupted during the course of driving of the diskette type electronic device, which may in turn corrupt data to be recorded on or reproduced from the IC memory. Thus, the button primary battery poses a problem of posing difficulty in effecting stable and normal recording and reproducing operations over a long time period.

In order to prevent corruption of data, there is a necessity for replacing a battery with a new one before the power of the battery has become depleted, thereby posing a practical problem of driving up costs drastically.

### SUMMARY OF THE INVENTION

The present invention has been conceived in light of the above-described realities and aims at providing a diskette type electronic device capable of being stably driven over a long time period.

In order to achieve the above object, according to the present invention, there is provided a diskette type electronic device attached to a reader/writer for recording and reproducing information on and from an information recording medium provided therein, comprising:

a diskette case, having a shape substantially identical with a diskette provided with a magnetic disk as the information recording medium;

an IC memory, provided as the information recording medium;

a communicator, which communicates information to be recorded on or reproduced from the IC memory with the reader/writer; and

a detachable power supply unit, including a rechargeable secondary battery which supplies power to the IC memory and the communicator.

In this configuration, the power supply unit can be used through repeated recharging. Further, since the unrechargeable primary battery is not used in the power supply unit, sufficient storage capacitance can be readily ensured for the power supply unit. Consequently, the diskette type electronic device according to the present invention can be driven stably over a long time period. Further, there is no necessity of replacing a brand new primary battery, thus enabling practical use of the diskette type electronic device at considerably low cost.

Preferably, a recess is formed in a principal face of the diskette case to accommodate the power supply unit therein. Here, a principal face of the power supply unit is flush with the principal face of the diskette case when the power supply unit is accommodated in the recess.

In this configuration, there is obviated a necessity for providing a closure member in a position where the power supply unit is to be housed. There can be realized elimination of a fear of occurrence of fracture in the closure member or loss of the closure member, as well as a reduction in the number of components and cost.

Preferably, the power supply unit includes a terminal which receives power from the reader/writer to recharge the secondary battery.

In this configuration, there is obviated a necessity for use of a charger compatible with the power supply unit at the time of recharging of the secondary battery of the power supply unit; rather, recharging of the secondary battery can be effected by attaching the diskette type electronic device to the reader/writer. Consequently, sufficient storage capacitance can be ensured for the power supply unit at all times at the time of recording and reproduction of information on and from IC memory.

### BRIEF DESCRIPTION OF THE DRAWINGS

The above objects and advantages of the present invention will become more apparent by describing in detail preferred exemplary embodiments thereof with reference to the accompanying drawings, wherein.

FIG. 1 is a schematic block diagram showing a diskette type electronic device according to one embodiment of the present invention; and

FIG. 2 is a diagram showing the state in which a power supply unit provided in the diskette type electronic device is detachably attached.

### DETAILED DESCRIPTION OF THE PREFERRED EMBODIMENTS

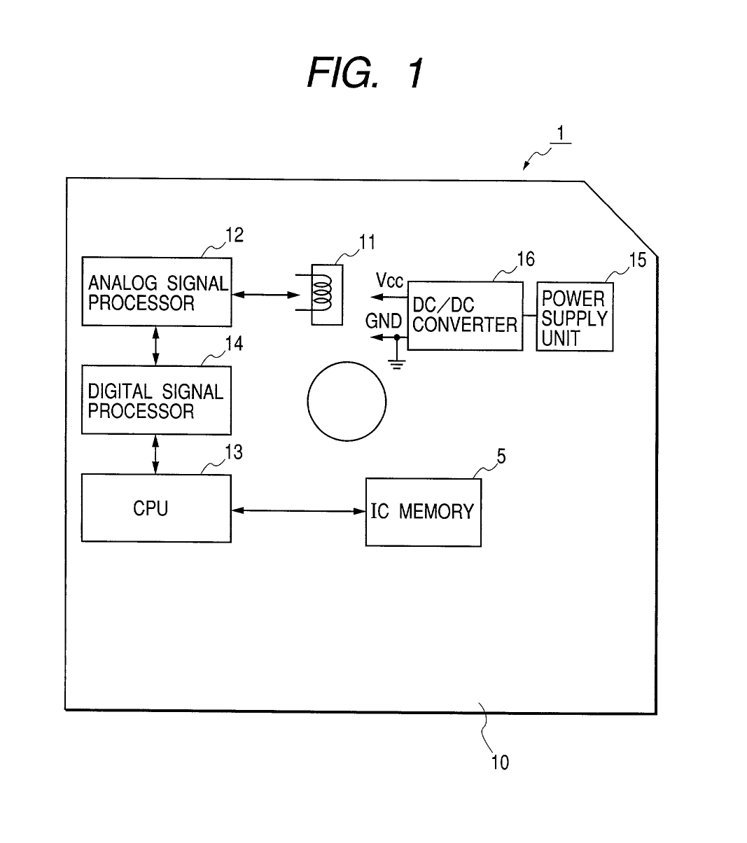

A preferred embodiment of the present invention will be described hereinbelow in detail by reference to the accompanying drawings. There will now be described hereunder a case where the present invention is applied to a diskette type electronic device 1 as shown in FIG. 1.

The diskette type electronic device 1 constructed by application of the present invention has a diskette case 10. The diskette case 10 has an outline substantially identical with that of a floppy disk (hereinafter called simply as a “diskette”) equipped with a magnetic disk of 3.5 inches diameter as an information recording medium.

Further, an IC memory 5 called, e.g., a solid-state floppy disk card (SSFDC), is detachably attached to the diskette type electronic device 1. The IC memory 5 may be fixedly housed in the diskette case 10 rather than being detachably provided. Here, since the IC memory 5 is provided detachably, the IC memory 5 can be replaced as required, thus enabling an increase in storage capacity which enables essential recording and reproduction of information.

A diskette is detachably attached to the diskette type electronic device 1. The diskette type electronic device 1 is also detachably attached to a reader/writer which records and reproduces information on and from a magnetic disk of the diskette. When the diskette type electronic device 1 is attached to the reader/writer, information can be recorded on and reproduced from the IC memory 5 through use of a magnetic head provided with the reader/writer.

Provided in the internal space of the diskette case 10 of the diskette type electronic device 1 are a magnetic coil 11 for communicating information with the magnetic head of the reader/writer; an analog signal processor 12 for subjecting to various types of signal processing operations an analog signal to be communicated by the magnetic coil 11; a CPU 13 for recording and reproducing information on and from the IC memory 5 through use of a digital signal; and a digital signal processor 14 for subjecting to digital processing the digital signal to be recorded and reproduced on and from the IC memory 5 by the CPU 13. The analog signal processor 12, the CPU 13, and the digital signal processor 14 embody the function of a communicator for communicating, with the reader/writer, information to be recorded and reproduced on and from the IC memory 5.

The diskette type electronic device 1 includes: a power supply unit 15 for supplying power to be used for driving the IC memory 5 and individual sections of the communicator; and a DC/DC converter 16 for stably supplying a supply voltage (Vcc) supplied from the power supply unit 15.

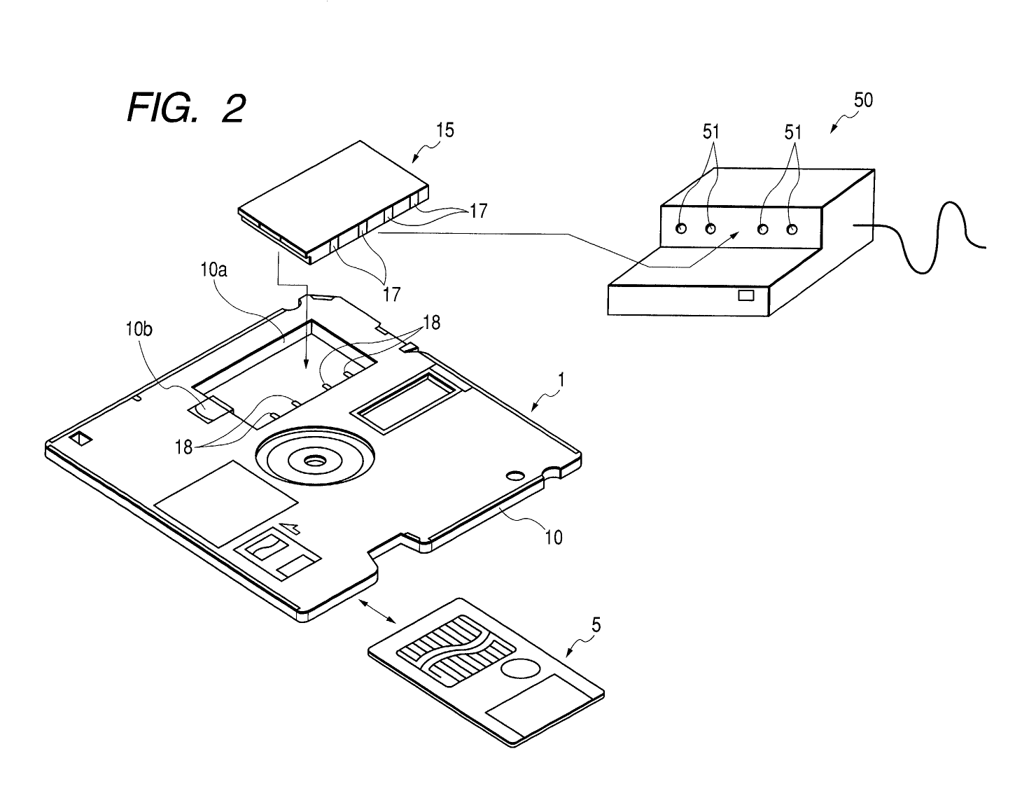

As shown in FIG. 2, a recess 10a for housing the power supply unit 15 is formed in one principal face of the diskette case 10 of the diskette type electronic device 1. The power supply unit 15 is detachably provided in the diskette case 10.

The power supply unit 15 has a rechargeable secondary battery provided therein. A plurality of terminals 17 connected to the secondary battery are provided so as to face the outside. The power supply unit 15 is also detachably attached to a charger 50 as shown in FIG. 2. While the power supply unit 15 is attached to the charger 50, the terminals 17 are brought into contact with a plurality of terminals 51 provided in the charger 50. Power is supplied to the power supply unit 15 by way of the terminals 51 of the charger 50, thereby recharging the secondary battery provided in the power supply unit 15.

The power supply unit 15 has an outline corresponding to the recess 10a formed in the diskette case 10. The outline of the power supply unit 15 is set so as to become essentially flush with the principal face of the diskette case 10 while the power supply unit 15 is housed in the recess 10a of the diskette case 10.

In relation to the diskette type electronic device 1, the power supply unit 15 wholly assumes substantially the same outline as that of the diskette while housed in the diskette case 10. The diskette type electronic device 1 is constructed in this way so as to obviate a necessity for a closure member to be used for housing the power supply unit 15. Thus, there is eliminated the fear of damage to or loss of a closure member.

A lock member 10b is provided in the position on the diskette case 10 which borders the recess 10a. The lock member 10b is forcefully moved in a predetermined direction by an urging member; e.g., a spring, thus fastening the power supply unit 15 while housed in the recess 10a. By applying force in an opposite direction, the power supply unit 15 can be removed from the recess 10a.

A plurality of terminals 18 are provided in positions within the recess 10a, the positions corresponding to the respective terminals 17 of the power supply unit 15. While the power supply unit 15 is housed in the recess 10a, the terminals 17 of the power supply unit 15 are brought into contact with the terminals 18 of the recess 10a. The power stored in the secondary battery of the power supply unit 15 is supplied to the DC/DC converter 16.

In relation to the diskette type electronic device 1 constructed in the manner as mentioned above, since the power supply unit 15 having a rechargeable secondary battery is detachably attached to the diskette case 10, the secondary battery of the power supply unit 15 can be used through repeated recharging. Further, since the unrechargeable primary battery is not used in the power supply unit 15, sufficient storage capacitance can be readily ensured for the power supply unit 15. Consequently, the diskette type electronic device 1 can be driven stably over a long time period.

In the foregoing description, the secondary battery of the power supply unit 15 is recharged while the power supply unit 15 is attached to the charger 50. Alternatively, for example, additional terminals are further provided in one side of the diskette case 10 of the diskette type electronic device 1 for receiving power from the reader/writer. The diskette type electronic device may be constructed so as to receive power by way of the additional terminals while remaining attached to the reader/writer. When the diskette type electronic device is attached to the reader/writer for recording and reproducing information on and from the IC memory 5, the power supply unit 15 can receive power from the reader/writer to recharge the secondary battery of the power supply unit 15. Consequently, sufficient storage capacitance can be ensured for the power supply unit 15 at all times.

Although the present invention has been shown and described with reference to specific preferred embodiments, various changes and modifications will be apparent to those skilled in the art from the teachings herein. Such changes and modifications as are obvious are deemed to come within the spirit, scope and contemplation of the invention as defined in the appended claims.

What is claimed is:

1. A diskette type electronic device attached to a reader/writer for recording and reproducing information on and from an information recording medium provided therein, the electronic device comprising:
a diskette case, having a shape substantially identical with a diskette provided with a magnetic disk as the information recording medium;
an IC memory, provided as the information recording medium;
a communicator, which communicates information to be recorded on or reproduced from the IC memory with the reader/writer; and
a detachable power supply unit, including a rechargeable secondary battery which supplies power to the IC memory and the communicator.

2. The diskette type electronic device as set forth in claim 1, wherein:
a recess is formed in a principal face of the diskette case to accommodate the power supply unit therein; and
a principal face of the power supply unit is flush with the principal face of the diskette case when the power supply unit is accommodated in the recess.

3. The diskette type electronic device as set forth in claim 1, wherein the power supply unit includes a terminal which receives power from the reader/writer to recharge the secondary battery.
